(19) United States
(12) Patent Application Publication
(10) Pub. No.: US 2014/0004631 A1
(43) Pub. Date: Jan. 2, 2014

(54) METHOD FOR MANUFCTURING LIGHT EMITTING DIODE PACKAGE

(71) Applicant: ADVANCED OPTOELECTRONIC TECHNOLOGY, INC., Hsinchu Hsien (TW)

(72) Inventors: CHUNG-MIN CHANG, Hukou (TW); CHIEN-LIN CHANG-CHIEN, Hukou (TW); HSUEN-FENG HU, Hukou (TW); CHANG-WEN SUN, Hukou (TW)

(73) Assignee: ADVANCED OPTOELECTRONIC TECHNOLOGY, INC., Hsinchu Hsien (TW)

(21) Appl. No.: 13/892,315

(22) Filed: May 13, 2013

(30) Foreign Application Priority Data
Jun. 29, 2012 (CN) 2012102210185

(51) Int. Cl. H01L 33/58

(52) U.S. Cl. CPC H01L 33/58
USPC 438/27

(57) ABSTRACT

A method for manufacturing a method for manufacturing a light emitting diode (LED) package includes following steps: providing a substrate and a blocking member formed on a top surface of the substrate; providing an LED chip and mounting the LED chip on the top surface of the substrate, the LED chip enclosed by the blocking member; providing a dispensing machine with glue, dispensing the glue in the blocking member to make the glue encapsulate the LED chip; and heating the glue to obtain a lens formed on the substrate directly.

### BACKGROUND

1. Technical Field

The present disclosure relates to semiconductor devices and, more particularly, to a method for manufacturing light emitting diode (LED) package.

2. Description of Related Art

A method for manufacturing an LED package includes following steps: providing a substrate and an LED chip; mounting the LED chip on the substrate; providing a lens and glue and adhering the lens to the substrate by the glue to make the lens covering the LED chip. However, the refractive index of the glue is different from that of the lens. Light emitted from the LED chip is prone to be reflected back into an interior of the lens by the glue. Thus, a light extraction efficiency of the LED package is disadvantageously affected.

Accordingly, it is desirable to provide a method for manufacturing an LED package which can overcome the described limitations.

### BRIEF DESCRIPTION OF THE DRAWINGS

FIGS. 1-2 are schematic views showing steps of a method for manufacturing an LED package of the present disclosure.

### DETAILED DESCRIPTION

Embodiment of a method for manufacturing an LED package will now be described in detail below and with reference to the drawings.

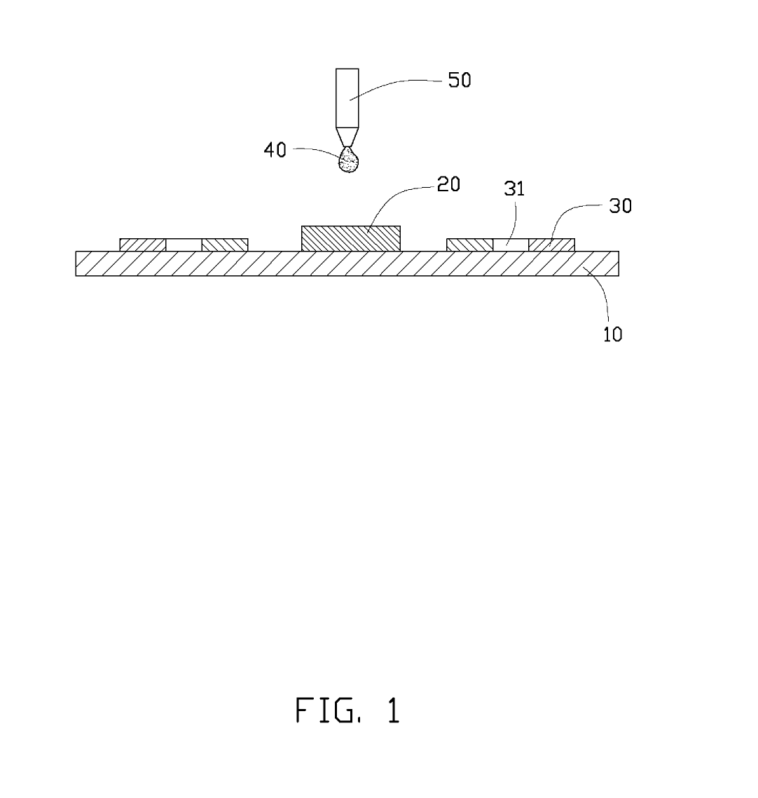

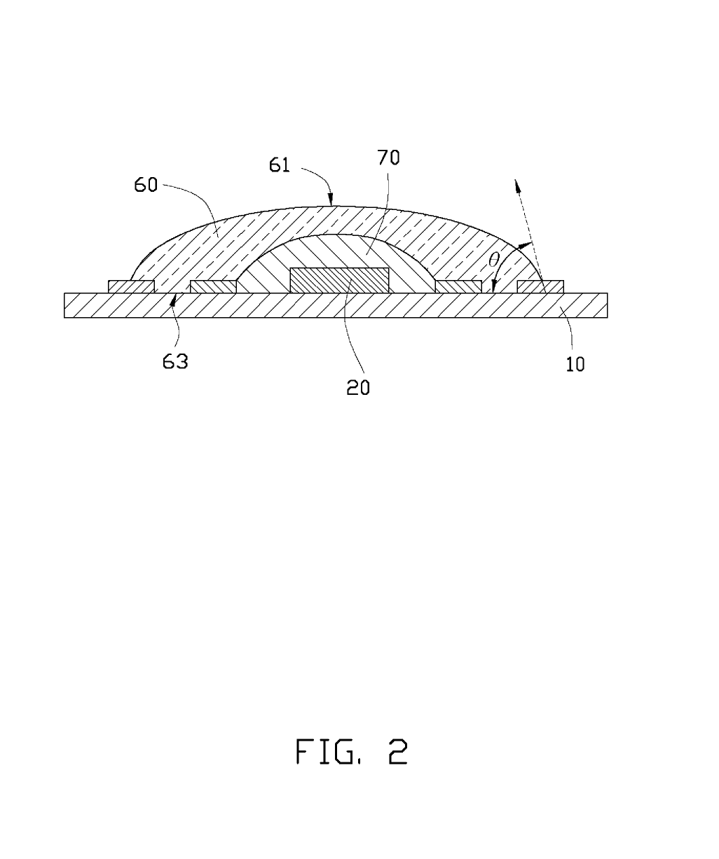

Referring to FIGS. 1-2, the first step is providing a substrate 10, forming a circuit (not shown) and a blocking member 30 on a top surface of the substrate 10. In this embodiment, the substrate 10 is made of material having good heat dissipation performance and being electrically insulating, for example, ceramic. The blocking member 30 is protruded upwardly from the top surface of the substrate 10 and made of hydrophobic material. The blocking member 30 is annular and a receiving groove 31 is defined a central portion therein along a circumference direction thereof. Alternatively, the blocking member 30 may be rectangular, trigonal or another required shaped.

The second step is providing an LED chip 20, mounting the LED chip 20 on the top surface of the substrate 10 and electrically connecting the circuit of the substrate 10. The LED chip 20 is enclosed by the blocking member 30. A height of the LED chip 20 is larger than that of the blocking member 30.

The third step is providing a dispensing machine 50 with glue 40, dispensing the glue 40 in the groove 31 and an inside of the blocking member 30 to encapsulate the LED chip 20 in the glue 40 and fill the groove 31. The glue 40 is a pure silica gel or a mixture mixed by a pure silica gel and phosphor powder.

The fourth step is heating the glue 40 to obtain a packaging layer 70 and a lens 60. The packaging layer 70 encloses the LED chip 20 therein and is located in the blocking member 30. A periphery of a bottom end of the packaging layer 70 contacts an inner surface of the blocking member 30. The lens 60 encloses the packaging layer 70 therein and a bottom end thereof is received in the groove 31. The lens 60 includes a top surface 61 and a bottom surface 63 connecting a bottom end of the top surface 61. In this embodiment, the top surface 61 is convex. The bottom surface 63 is plane and directly formed on the top surface of the substrate 10. A tangent of the top surface 61 extends through a joint of the top surface 61 and the bottom surface 63. A contacting angle θ is defined between the tangent and the bottom surface 63. When the contacting angle θ is more larger, light reflected back into an interior of the lens 60 and the package layer 70 by the top surface 61 is more less. If the contacting angle θ is large enough, a light extraction efficiency of the LED chip 20 is good. In this embodiment, the contacting angle θ is not less than 75 degrees.

In this disclosure, the lens 60 is formed on the substrate 10 directly, so the glue is not need to distributed between the lens 60 and the substrate 10 which reflects light back into the lens 60. Therefore, the light extraction efficiency of the LED chip 20 is improved. Further, the lens 60 has a larger contacting angle, a majority of light emitted from the LED chip 20 can radiates out from the top surface 61. Thus, the light extraction efficiency of the LED chip 20 is improved.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for manufacturing a light emitting diode (LED) package comprising following steps:
providing a substrate and a blocking member formed on a top surface of the substrate;
providing an LED chip and mounting the LED chip on the top surface of the substrate, the LED chip enclosed by the blocking member;
providing a dispensing machine with glue, dispensing the glue in the blocking member to make the glue encapsulate the LED chip; and
heating the glue to obtain a lens formed on the substrate directly.

2. The method of claim 1, wherein the lens comprises a top surface and a bottom surface connecting a bottom end of the top surface, a tangent of the top surface extends through a joint of the top surface and the bottom surface to define a contacting angle between the tangent and the bottom surface, and the contacting angle is not less than 75 degrees.

3. The method of claim 1, wherein the top surface is convex and the bottom surface is plane.

4. The method of claim 1, wherein further comprises a packaging layer formed in the blocking member and enclosed by the lens.

5. The method of claim 3, wherein the blocking member is protruded upwardly from the top surface of the substrate and made of hydrophobic material.

6. The method of claim 5, wherein the blocking member is annular and a receiving groove is defined a central portion therein along a circumference direction thereof, the packaging layer is enclosed by the blocking member and a bottom end of the lens is received in the groove.

7. The method of claim 6, wherein a periphery of a bottom end of the packaging layer contacts an inner surface of the blocking member.

8. The method of claim 6, wherein a height of the LED chip is larger than that of the blocking member.

9. The method of claim 5, wherein the glue is a pure silica gel or a mixture mixed by a pure silica gel and phosphor powder.
